(19) United States
(12) Patent Application Publication
(10) Pub. No.: US 2013/0148456 A1
(43) Pub. Date: Jun. 13, 2013

(54) VOLTAGE REGULATOR WITH IMPROVED LOAD REGULATION AND VOLTAGE REGULATING METHOD

(71) Applicants: Min-Hyung CHO, Daejeon (KR); Yi-Gyeong KIM, Daejeon (KR); Tae Moon ROH, Daejeon (KR); Woo Seok YANG, Daejeon (KR); Jong-Kee KWON, Daejeon (KR); Jongdae KIM, Daejeon (KR)

(72) Inventors: Min-Hyung CHO, Daejeon (KR); Yi-Gyeong KIM, Daejeon (KR); Tae Moon ROH, Daejeon (KR); Woo Seok YANG, Daejeon (KR); Jong-Kee KWON, Daejeon (KR); Jongdae KIM, Daejeon (KR)

(73) Assignee: Electronics and Telecommunications Research Institute, Daejeon (KR)

(21) Appl. No.: 13/545,877

(22) Filed: Jul. 10, 2012

(30) Foreign Application Priority Data
Dec. 12, 2011 (KR) 10-2011-0133020

(51) Int. Cl. G05F 1/10; G11C 5/14

(52) U.S. Cl. 365/226; 323/282

(57) ABSTRACT

Provided is a voltage supply circuit using a charge pump. The voltage supply circuit enhances charge pump output voltage fluctuation characteristics depending on load variation of a charge pump voltage generator (load regulation characteristics) when receiving an operation power supply voltage of the charge pump through a regulator. The voltage supply circuit is configured to feed back fluctuation of a charge pump output voltage to a charge pump voltage regulator. The fluctuation of the charge pump output voltage is compensated through fluctuation of an output voltage of the charge pump to active enhance the load regulation characteristics.

### CROSS-REFERENCE TO RELATED APPLICATIONS

This US non-provisional patent application claims priority under 35 USC §119 to Korean Patent Application No. 10-2011-0133020, filed on Dec. 12, 2011, the entirety of which is hereby incorporated by reference.

### BACKGROUND OF THE INVENTION

The present general inventive concept relates to voltage supplies and, more particularly, to a voltage supply circuit for improving load variation characteristics which can minimize or reduce charge pump output voltage fluctuation depending on load variation and an output voltage supply method.

A voltage supply circuit may employ a charge pump.

A charge pump is a kind of DC-DC converter that converts a specific voltage into another voltage. A typical charge pump employs a capacitor without an inductor. The charge pump transfers charges charged to a capacitor to the next-stage capacitor to generate a converted voltage.

The charge pump is mainly used as a circuit for generating and supplying a voltage exceeding the range of a power supply voltage supplied to a semiconductor chip inside the semiconductor chip, i.e., a voltage, or a negative voltage, higher than the power supply voltage supplied to the semiconductor chip.

In general, a charge pump power supply voltage input to a charge pump is generated at a voltage regulator. The charge pump performs charge pumping on the charge pump power supply voltage in response to a clock to generate a charge pump output voltage.

A load connected to an output terminal of the charge pump may vary greatly. For example, a load may vary abruptly or a load may vary periodically due to a switching circuit or the like incorporated in the load.

When load variation is great, output voltages of a charge pump drop sequentially. Accordingly, there is a need for improved measures to effectively compensate the sequential voltage drop.

### SUMMARY OF THE INVENTION

Embodiments of the inventive concept provide a voltage supply circuit and a method for supplying a charge pump output voltage to a load using a charge pump.

According to an aspect of the inventive concept, a voltage supply circuit may include a voltage regulator configured to receive an external power supply voltage to generate a charge pump power supply voltage based on comparison between a reference voltage and a feedback voltage; and a charge pump configured to perform charge pumping on the charge pump power supply voltage according to a clock to generate a charge pump output voltage. The charge pump feeds back the charge pump output voltage to the voltage regulator through a feedback line connected to the voltage regulator.

In some embodiments, when the charge pump output voltage fluctuates depending on load variation, the feedback voltage may fluctuate to compensate fluctuation of the charge pump output voltage.

In some embodiments, the reference voltage may be generated from a bandgap reference circuit.

In some embodiments, the voltage regulator may further include a voltage-controlled current source circuit to obtain the feedback voltage depending on an output of the voltage-controlled current source circuit.

In some embodiments, the feedback voltage may be obtained at the junction between an output terminal of the voltage-controlled current source circuit and a voltage-dividing terminal appearing when the charge pump power supply voltage is divided at a constant ratio.

In some embodiments, the feedback line may be coupled between an input terminal of the voltage-controlled current source circuit and a charge pump output voltage output terminal of the charge pump.

According to an alternative aspect of the inventive concept, a voltage supply circuit may include a voltage regulator configured to receive an external power supply voltage to generate a charge pump power supply voltage based on comparison between a reference voltage and a feedback voltage; and a Dickson-type charge pump configured to perform charge pumping on the charge pump power supply voltage to supply a charge pump output voltage to a load. The charge pump feeds back the charge pump output voltage to the voltage regulator through a feedback line connected to the voltage regulator.

In some embodiments, the voltage regulator may include a comparator configured to compare the reference voltage with the feedback voltage to generate a compared output; a driving transistor configured to drive the external power supply voltage according to the compared output to generate the charge pump output voltage; a voltage-dividing resistor unit configured to divide the charge pump power supply voltage at a set resistance ratio to generate the feedback voltage; and a voltage-controlled current source circuit configured to generate feedback current controlled depending on the charge pump output voltage received through the feedback line and apply the feedback current to the voltage-dividing resistor unit.

In some embodiments, the reference voltage may be generated from a bandgap reference circuit generating a voltage irrespective of fluctuation of the external power supply voltage.

In some embodiments, the voltage-controlled current source circuit may include a comparator configured to compare the charge pump output voltage with a controlled feedback voltage to generate a controlled output; first and second transistors configured to generate the external power supply voltage in response to the controlled output commonly; and a resistor coupled between the first transistor and a ground to determine the controlled feedback voltage. The feedback current is supplied from the second transistor.

In some embodiments, when the charge pump output voltage fluctuates depending on variation of the load, the feedback voltage may fluctuate due to the feedback line to compensate the fluctuation of the charge pump output voltage.

In some embodiments, each of the first and second transistors may be a MOS field effect transistor.

In some embodiments, the voltage regulator may raise the charge pump power supply voltage when the charge pump output voltage drops.

In some embodiments, the voltage regulator may lower the charge pump power supply voltage when the charge pump output voltage rises.

According to another aspect of the inventive concept, a method for supplying a charge pump output voltage to a load using a charge pump may include receiving an external power supply voltage to generate a charge pump power supply voltage based on comparison between a reference voltage and a feedback voltage; performing charge pumping on the charge pump power supply voltage according to a clock to generate the charge pump output voltage; and performing feedback such that the charge pump output voltage has an effect on the generation of the charge pump power supply voltage.

In some embodiments, the charge pump power supply voltage may be generated high when the charge pump output voltage drops with variation of the load.

In some embodiments, the charge pump power supply voltage may be generated low when the charge pump output voltage rises with variation of the load.

In some embodiments, charge pumping on the charge pump power supply voltage may be performed by means of a Dickson-type charge pump.

In some embodiments, performing feedback may allow the feedback voltage to be adjusted depending on variation of the load.

In some embodiments, the load is used to drive a semiconductor memory device.

### BRIEF DESCRIPTION OF THE DRAWINGS

The inventive concept will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the inventive concept.

FIG. 1 is a circuit diagram of a typical Dickson-type charge pump.

FIG. 2 is a circuit diagram illustrating the case where a load is connected to the circuit in FIG. 1.

FIG. 3 is a circuit diagram of a conventional voltage supply circuit.

FIG. 4 is a circuit diagram of a power supply circuit according to an embodiment of the inventive concept.

FIG. 5 is a circuit diagram according to an implementation embodiment in FIG. 4.

FIG. 6 is a detailed exemplary diagram of a voltage-controlled current source circuit in FIG. 5.

### DETAILED DESCRIPTION

The objects, advantages, and features of the inventive concept will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose examples of the inventive concept and to let those skilled in the art understand the nature of the inventive concept.

In the specification, it will also be understood that when an element or parts are referred to as being “on” a target element block, it can be directly on the target element block, or intervening another element may also be present.

Throughout the drawings, the same or similar reference numerals designate the same or similar elements. In some drawings, relationships between elements and lines are explained for clarity of the inventive concept and other elements or electronic circuit blocks may be further provided.

It is to be noted that embodiments described and exemplified herein should be interpreted to include complementary embodiments thereof. Also it is to be noted that basic explanations with respect to basic shape, manufacturing, and operation of a charge pump will not be done in detail to prevent ambiguity of the inventive concept.

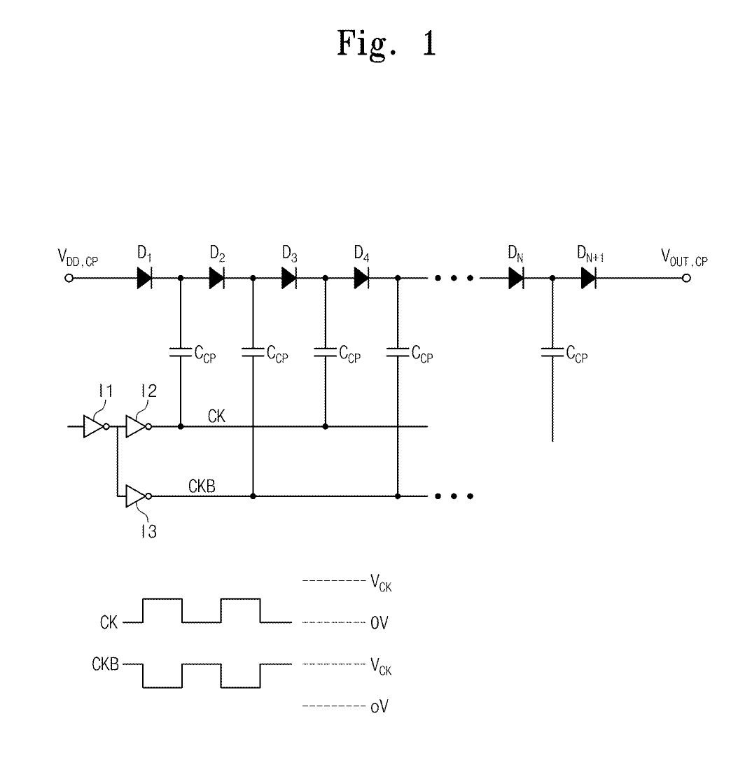

In the following description, for the purpose of explanation, numerous details are set forth in order to provide a thorough understanding of the embodiments of the inventive concept. However, it will be apparent to one skilled in the art that these specific details are not required in order to practice the embodiments of the inventive concept. A conventional charge pump and a voltage supply circuit employing the conventional charge pump will now be described below with reference to FIGS. 1 to 3.

FIG. 1 is a circuit diagram of a typical Dickson-type charge pump.

The Dickson-type charge pump includes a diode and a capacitor as a unit cell. The diode functions as a switch to determine a charge transfer direction. The Dickson-type charge pump includes a plurality of stages arranged in cascade. Pumping of the charge pump is done by alternately driving capacitors with clock signals CK and CKB having opposite phases.

An input voltage _{VDD,CP}, a clock voltage V_{CK}, and an output voltage of V_{OUT,CP} of the charge pump have a relationship, as shown below in Equation (1).

V_{OUT,CP}=V_{DD,CP}+N×(V_{CK}−V_{D,TH})−V_{D,TH} Equation (1)

In the Equation (I), V_{D,TH} represents a forward turn-on voltage of a diode used as a charge transfer switch, and N represents the number of stages of a charge pump cell that are arranged in cascade. As can be seen from the relationship in the Equation (1), an output voltage of the charge pump is determined by an input voltage V_{DD,CP} and a clock voltage V_{CK} of the charge pump, the number N of stages of the charge pump, and the forward turn-on voltage V_{D,TH} of a diode used as a charge transfer switch. The forward turn-on voltage V_{D,TH} is a fixed value due to device characteristics and cannot vary during a circuit operation. A value corresponding to the forward turn-on voltage V_{D,TH} is significantly reduced through improvement of a switch circuit used in the charge pump. Generally, the clock voltage V_{CK} used in the charge pump matches a power supply voltage V_{DD,CP} of the charge pump. Therefore, the relationship in the Equation (1) is simply expressed as shown below in Equation (2).

V_{OUT,CP}=(N+1)×V_{DD,CP}−(N+1)×V_{D,TH} Equation (2)

That is, considering a fixed turn-on voltage of a charge transfer switch, an output voltage of a charge pump is determined by the number of stages of the charge pump.

When a load Iload is connected to the charge pump in FIG. 1 and the charge pump operates at a frequency of f_{CLK}(=1/T_{CLK}), a charge pump output voltage in a steady state considering load current IL supplied to a load from the charge pump is given by Equation (3).

$${V}_{OUT \cdot CP} = [ ( N + 1 ) \times {V}_{DD \cdot CP} - ( N + 1 ) \times {V}_{D \cdot TH} ] - N \times \frac{{I}_{L}}{{C}_{CP} \times {f}_{CLK}} \qquad Equation ( 3 )$$

That is, the load connected to an output of the charge pump causes a voltage in the steady state to drop by a voltage determined by a capacitor C_{CP}, load current I_{L}, an operation frequency f_{CLK} used in the charge pump.

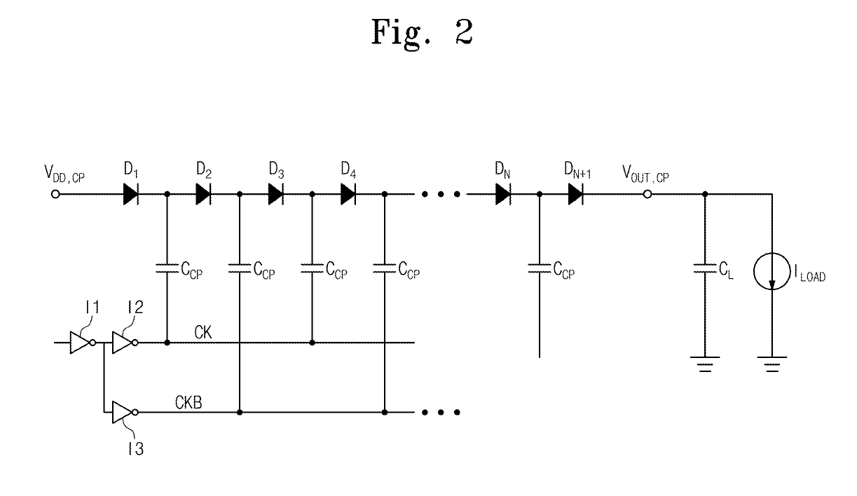

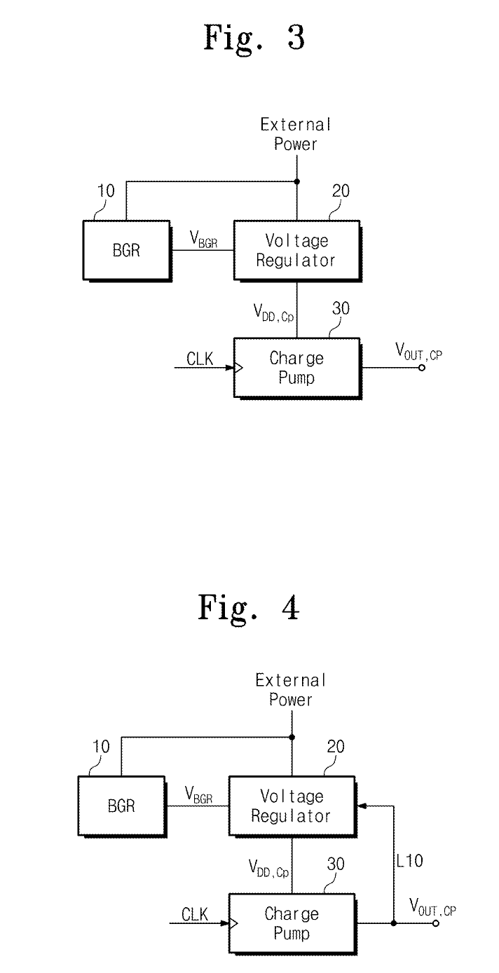

FIG. 2 is a circuit diagram illustrating the case where a load is connected to the circuit in FIG. 1, and FIG. 3 is a circuit diagram of a conventional voltage supply circuit.

A conventional semiconductor chip is designed to operate under the condition that an operating power supply voltage is within ±10 percent range of a reference power supply voltage. However, there may be a requirement for a chip operating in a wide power supply voltage range (e.g., 1.6 to 3.6 volts) exceeding a conventional power supply voltage range. A constant voltage is required in a variable power supply voltage chip operating in the wide power supply voltage range. The required constant voltage may exceed the power supply voltage range of a chip. Accordingly, as shown in FIG. 3, a power supply circuit is employed which includes a charge pump 30, a bandgap reference circuit (BGR) circuit 10 generating a reference voltage signal irrespective of fluctuation of a power supply voltage applied to a chip, and a voltage regulator 20 regulating a power supply voltage for operating the charge pump 30. The voltage regulator 20 may be a low-dropout (LDO) regulator.

A power supply voltage supplied to the charge pump 30 through the voltage regulator 20 is determined based on a BGR voltage V_{BGR}.

In FIG. 3, a power supply voltage V_{DD,CP} supplied to the charge pump 30 and a BGR reference voltage V_{BGR} have a linear relationship, as shown below in Equation (4).

V_{DD,CP}=α×V_{BGR} Equation (4)

When a load is connected to a power supply circuit using a charge pump, output signal characteristics of the charge pump power supply circuit vary depending on characteristics of the load. This relationship can be confirmed from the Equation (3).

When current I_{L} to be supplied from a charge pump to a load is small, there is a small difference between an output voltage of the charge pump and an ideal value. Meanwhile, when the current I_{L} to be supplied from a charge pump to a load is large, voltage reduction caused by the supply of load current increases and thus an error of the output voltage becomes large.

When the reduction of the output voltage becomes large with the increase of the load current, capability of supplying current to the load is improved by increasing the charge transfer amount of the charge pump to compensate the large voltage reduction.

Conventionally, there have been methods used to increase the charge transfer amount of a charge pump.

As one method for increasing the amount of charges transferred, a capacitor for use in a charge pump is made large in size. However, this method encounters the disadvantage that area efficiency is lowered because a chip must also be made large in size.

As another method for increasing the amount of charges transferred, an operation frequency of a charge pump is made high. For example, Korean Patent No. 10-2008-0112518 (entitled “BOOSTING VOLTAGE GENERATOR COMPRISING HIGH EFFICIENCY CHARGE PUMP AND METHOD THEREOF”) is disclosed as a prior-art patent. In the prior-art patent, two charge pumps operating in opposite phases are connected in parallel to an output. The size of a capacitor is substantially doubled, and the operation frequency is also substantially doubled to use both of the two phases.

When a load connected to an output of a charge pump varies greatly, i.e., the load varies abruptly or the load may vary periodically due to a switching circuit or the like incorporated in the load, an output voltage of the charge pump drops instantaneously. Accordingly, it could be understood that a frequency of the charge pump must always be changed depending on variation of an output load.

In the embodiment of the inventive concept, the circuit configuration illustrated in FIG. 4 is provided to efficiently compensate charge pump output voltage fluctuation depending on load variation without individually changing and controlling operation frequencies of the charge pump.

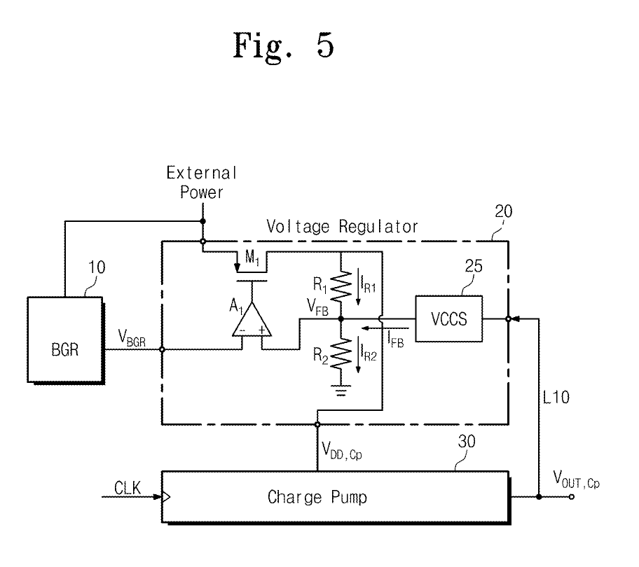

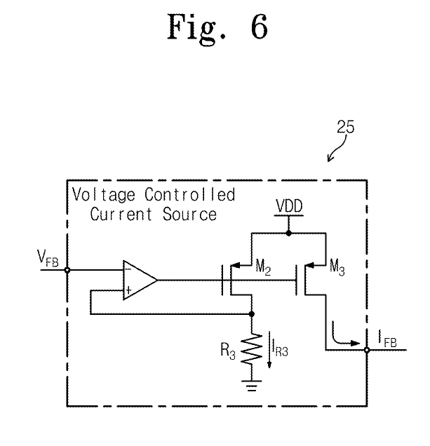

FIG. 4 is a circuit diagram of a power supply circuit according to an embodiment of the inventive concept, and FIG. 5 is a circuit diagram according to an implementation embodiment in FIG. 4. FIG. 6 is a detailed exemplary diagram of a voltage-controlled current source circuit in FIG. 5.

Referring to FIG. 4, the configuration of a voltage supply circuit including a voltage regulator 20 and a charge pump 30 is shown.

The voltage regulator 20 receives an external power supply voltage to generate a charge pump power supply voltage according to comparison between a reference voltage and a feedback voltage.

The charge pump 30 pumps the charge pump power supply voltage depending on a clock to generate a charge pump output voltage Vout.

In FIG. 4, the charge pump 30 feedbacks the charge pump output voltage Vout to the voltage regulator 20 through a feedback line L10 connected to the voltage regulator 20.

Thus, when the charge pump output voltage Vout fluctuates depending on load variation, the feedback voltage fluctuates to compensate the fluctuation of the charge pump output voltage Vout.

A reference voltage applied to the voltage regulator 20 is generated from a bandgap reference circuit 10.

In conclusion, the configuration in FIG. 4 including the circuit configuration in FIG. 3 is provided such that an output voltage of a charge pump is fed back to the voltage regulator 20 to change an output voltage of the voltage regulator 20, i.e., an operating voltage of the charge pump according to the output voltage of the charge pump.

More specifically, when an output voltage of the charge pump 30 drops, an output voltage of the voltage regulator 20 rises. Meanwhile, when the output voltage of the charge pump 30 rises, the output voltage of the voltage regulator 20 drops. Thus, charge pump output voltage fluctuation depending on load variation of the charge pump is compensated.

A relationship between an output voltage and a charge pump power supply voltage of the charge pump 30 can be confirmed through the Equation (3). According to the charge pump output voltage relationship in the Equation (3), when the output voltage of the charge pump drops, a power supply voltage V_{DD,CP} of the charge pump is made high, except for a size and an operation frequency of a capacitor for use in the charge pump, to make the output voltage of the charge pump high. This is because the amount of charges stored in the capacitor of the charge pump increases for one clock cycle as an operation power supply voltage of the charge pump rises. As a result, when the charge transfer amount is large, charge pump output voltage reduction caused by a high load is compensated.

Referring to FIG. 5 illustrating a circuit diagram according to an implementation embodiment of FIG. 4, a detailed example of the voltage regulator 20 is shown.

The voltage regulator 20 includes a comparator A1 comparing a reference voltage V_{BGR} with a feedback voltage V_{FB} to generate a compared output, a drive transistor M1 driving an external power supply voltage to generate a charge pump power supply voltage V_{DD}, voltage-dividing resistor units R1 and R2 dividing the charge pump power supply voltage according to a set resistance ratio to generate the feedback voltage V_{FB}, and a voltage-controlled current source circuit 25 generating feedback current IFB controlled depending on a charge pump output voltage V_{OUT} and applying the feedback voltage V_{FB} to a voltage-dividing terminal of the voltage-dividing resistor unit.

As shown in FIG. 6 illustrating a detailed example of the voltage-controlled current source circuit in FIG. 5, the voltage-controlled current source unit 25 includes a comparator comparing a charge pump output voltage with a controlled feedback voltage to generate a controlled output, first and second transistors M2 and M3 driving an external power supply voltage in response to the controlled output, and a resistor R3 coupled between the first transistor M2 and a ground to determine the controlled feedback voltage. Feedback current I_{FB} is supplied from the second transistor M3.

The above-described circuit in FIG. 5 is the configuration obtained by implementing the voltage regulator 20 in FIG. 4 as an embodiment. Except for the voltage-controlled current source (VCCS) circuit 25, an output voltage V_{DD,CP} of a typical regulator may be determined as shown below in Equation (5).

$${V}_{DD \cdot CP} = {V}_{BGR} \times ( 1 + \frac{{R}_{1}}{{R}_{2}} ) \qquad Equation ( 5 )$$

The operation in the case where the VCCS circuit 25 is added will now be described below.

The VCCS circuit 25 is a circuit having an input signal as a voltage signal and an output signal as a current signal. According to the configuration shown in FIG. 6, output current increases as an input voltage increases and decreases as the input voltage decreases.

The output voltage intensity of a charge pump is converted into current I_{FB} through the above VCCS circuit 25, and the converted current I_{FB} is supplied to the junction between resistors R1 and R2 in the voltage regulator 20. Accordingly, when an output voltage of the charge pump 30 increases due to load variation, the intensity of the current I_{FB} increases and thus current I_{R1} flowing through the resistor R1 decreases by the increasing I_{FB}. Accordingly, a voltage formed through the resistor R1 decreases by (I_{FB}×R1) and thus the intensity of the charge pump power supply voltage supplied to the charge pump V_{DD,CP} decreases by (I_{FB}×R1). As a result, the output voltage of the charge pump 30 also decreases.

In contrast, when the output voltage of the charge pump 30 is made small by load variation, the intensity of the current I_{FB} decreases and thus the current I_{R1} flowing through the resistor R1 increases by the increasing I_{FB}. Accordingly, the voltage formed through the resistor R1 increases by (I_{FB}×R1). As a result, the output voltage of the charge pump 30 also decreases. Through the above operations, the circuit illustrated in FIG. 5 may operate in the direction to compensate output voltage fluctuation of the charge pump 30.

FIG. 6 illustrates a detailed embodiment of the VCCS circuit 25 shown in FIG. 5. The above-configured circuit in FIG. 6 converts an input voltage into output current that is in proportion to the intensity of the input voltage. A relationship between output current IFB and an input voltage VFB is defined as a relationship in Equation (6).

$${I}_{FB} = {I}_{R 3} \times \frac{{( W / L )}_{M 3}}{{( W / L )}_{M 2}} = {V}_{FB} \times \frac{1}{{R}_{3}} \times \frac{{( W / L )}_{M 3}}{{( W / L )}_{M 2}} \qquad Equation ( 6 )$$

As set forth above, a voltage supply circuit may be configured to compensate charge pump output voltage fluctuation caused by load variation. However, a circuit having the same functions and effects may be fabricated by variation of the circuit configuration in FIGS. 5 and 6.

According to the embodiments of the inventive concept described above, since fluctuation of a charge pump output voltage is actively compensated through a feedback loop, charge pump output voltage fluctuation caused by load variation can be minimized or reduced.

While the inventive concept has been described with reference to illustrative embodiments, this description is not intended to be construed in a limiting sense. It will be clearly understood by those skilled in the art that foregoing description is merely by way of example and is not a limitation on the scope of the inventive concept. Various modifications and combinations of the illustrative embodiments, as well as other embodiments of the inventive concept, will be apparent to persons skilled in the art upon reference to the description. For example, in different cases, the configuration of a voltage regulator shown in FIG. 5 or the detailed configuration of a voltage-controlled current source circuit shown in FIG. 6 may be modified or changed without departing from the spirit and scope of the inventive concept as defined by the following claims.

What is claimed is:

1. A voltage supply circuit comprising:
a voltage regulator configured to receive an external power supply voltage to generate a charge pump power supply voltage based on comparison between a reference voltage and a feedback voltage; and
a charge pump configured to perform charge pumping on the charge pump power supply voltage according to a clock to generate a charge pump output voltage,
wherein the charge pump feeds back the charge pump output voltage to the voltage regulator through a feedback line connected to the voltage regulator.

2. The voltage supply circuit as set forth in claim 1, wherein when the charge pump output voltage fluctuates depending on load variation, the feedback voltage fluctuates to compensate fluctuation of the charge pump output voltage.

3. The voltage supply circuit as set forth in claim 1, wherein the reference voltage is generated from a bandgap reference circuit.

4. The voltage supply circuit as set forth in claim 1, wherein the voltage regulator further comprises a voltage-controlled current source circuit to obtain the feedback voltage depending on an output of the voltage-controlled current source circuit.

5. The voltage supply circuit as set forth in claim 4, wherein the feedback voltage is obtained at the junction between an output terminal of the voltage-controlled current source circuit and a voltage-dividing terminal in which the charge pump power supply voltage is divided at a constant ratio.

6. The voltage supply circuit as set forth in claim 5, wherein the feedback line is coupled between an input terminal of the voltage-controlled current source circuit and a charge pump output voltage output terminal of the charge pump.

7. A voltage supply circuit comprising:
a voltage regulator configured to receive an external power supply voltage to generate a charge pump power supply voltage based on comparison between a reference voltage and a feedback voltage; and
a Dickson-type charge pump configured to perform charge pumping on the charge pump power supply voltage to supply a charge pump output voltage to a load,
wherein the charge pump feeds back the charge pump output voltage to the voltage regulator through a feedback line connected to the voltage regulator.

8. The voltage supply circuit as set forth in claim 7, wherein the voltage regulator comprises:
a comparator configured to compare the reference voltage with the feedback voltage to generate a compared output;
a driving transistor configured to drive the external power supply voltage according to the compared output to generate the charge pump output voltage;
a voltage-dividing resistor unit configured to divide the charge pump power supply voltage at a set resistance ratio to generate the feedback voltage; and
a voltage-controlled current source circuit configured to generate feedback current controlled depending on the charge pump output voltage received through the feedback line and apply the feedback current to the voltage-dividing resistor unit.

9. The voltage supply circuit as set forth in claim 8, wherein the reference voltage is generated from a bandgap reference circuit generating a voltage irrespective of fluctuation of the external power supply voltage.

10. The voltage supply circuit as set forth in claim 8, wherein the voltage-controlled current source circuit comprises:
a comparator configured to compare the charge pump output voltage with a controlled feedback voltage to generate a controlled output;
first and second transistors configured to generate the external power supply voltage in response to the controlled output commonly; and
a resistor coupled between the first transistor and a ground to determine the controlled feedback voltage,
wherein the feedback current is supplied from the second transistor.

11. The voltage supply circuit as set forth in claim 8, wherein when the charge pump output voltage fluctuates depending on variation of the load, the feedback voltage fluctuates due to the feedback line to compensate the fluctuation of the charge pump output voltage.

12. The voltage supply circuit as set forth in claim 8, wherein each of the first and second transistors is a MOS field effect transistor.

13. The voltage supply circuit as set forth in claim 8, wherein the voltage regulator raises the charge pump power supply voltage when the charge pump output voltage drops.

14. The voltage supply circuit as set forth in claim 8, wherein the voltage regulator lowers the charge pump power supply voltage when the charge pump output voltage rises.

15. A method for supplying a charge pump output voltage to a load using a charge pump, comprising:
receiving an external power supply voltage to generate a charge pump power supply voltage based on comparison between a reference voltage and a feedback voltage;
performing charge pumping on the charge pump power supply voltage according to a clock to generate the charge pump output voltage; and
performing feedback such that the charge pump output voltage has an effect on the generation of the charge pump power supply voltage.

16. The method as set forth in claim 15, wherein the charge pump power supply voltage is generated high when the charge pump output voltage drops with variation of the load.

17. The method as set forth in claim 15, wherein the charge pump power supply voltage is generated low when the charge pump output voltage rises with variation of the load.

18. The method as set forth in claim 15, wherein charge pumping on the charge pump power supply voltage is performed by means of a Dickson-type charge pump.

19. The method as set forth in claim 15, wherein performing feedback allows the feedback voltage to be adjusted depending on variation of the load.

20. The method as set forth in claim 15, wherein the load is used to drive a semiconductor memory device.
